(19) United States
(12) Patent Application Publication
(10) Pub. No.: US 2013/0081673 A1
(43) Pub. Date: Apr. 4, 2013

(54) ARCHED PHOTOVOLTAIC MODULE

(71) Applicants: Zach Kinyon, (US); Nick McKibben, (US)

(72) Inventors: Zach Kinyon, (US); Nick McKibben, (US)

(73) Assignee: SunPower Corporation, San Jose, CA (US)

(21) Appl. No.: 13/250,990

(22) Filed: Sep. 30, 2011

(51) Int. Cl. H01L 31/048; H05K 13/04

(52) U.S. Cl. 136/251; 29/592.1

(57) ABSTRACT

A photovoltaic module can include an outer surface with an outwardly bulged convex shape. The outer surface can be curved about its longitudinal axis and/or transverse axis. Optionally, the outer surface can be bulged in a generally spherical shape. The convex shape of the outer surface of the PV module can provide the outer surface with additional stiffness, and/or cause water to flow away from the center of the panel toward its edges, thereby reducing soiling caused by accumulated water, debris, and dust and/or other benefits.

### BACKGROUND

1. Technical Field

Embodiments of the subject matter described herein relate generally to solar collectors. More particularly, embodiments of the subject matter relate to photovoltaic panels designed to reduce soiling and methods for manufacturing the same.

2. Description of the Related Art

Solar power has long been viewed as an important alternative energy source. To this end, substantial efforts and investments have been made to develop and improve upon solar energy collection technology. Of particular interest are industrial- or commercial-type applications in which relatively significant amounts of solar energy can be collected and utilized in supplementing or satisfying power needs.

Solar photovoltaic systems (or simply “photovoltaic systems”) employ solar panels made of silicon or other materials (e.g., III-V cells such as GaAs) to convert sunlight into electricity. Photovoltaic systems typically include a plurality of photovoltaic (PV) modules (or “solar tiles”) interconnected with wiring to one or more appropriate electrical components (e.g., switches, inverters, junction boxes, etc.). The PV module conventionally consists of a PV laminate or panel generally forming an assembly of crystalline or amorphous semiconductor devices (“PV cells”) electrically interconnected and encapsulated within a weather-proof barrier. One or more electrical conductors are housed inside the PV laminate through which the solar-generated current is conducted.

Regardless of an exact construction of the PV laminate, most PV applications entail placing an array of PV modules at the installation site in a location where sunlight is readily present. This is especially true for commercial or industrial applications in which a relatively large number of PV modules are desirable for generating substantial amounts of energy, with the rooftop of the commercial building providing a convenient surface at which the PV modules can be placed.

As a point of reference, many commercial buildings have large, flat roofs that are inherently conducive to placement of a PV module array, and are the most efficient use of existing space. While rooftop installation is thus highly viable, certain environment constraints must be addressed.

For example, PV laminates are generally flat or planar. Thus, at some latitudes, it can be sufficiently efficient to install PV laminates in a precisely horizontal orientation. At other latitudes, it is more efficient to install PV laminates at a tilted angle, relative to a flat rooftop (i.e., toward the southern sky for northern hemisphere installation, or toward the northern sky for southern hemisphere installations). Additionally, PV laminates should be installed with frames that are sufficiently strong to withstand any environmental forces, such as wind or snow.

In light of the above, PV modules for commercial installations include robust frames for maintaining the PV laminate relative to the installation surface (e.g., penetrating-type mounting in which bolts are driven through the rooftop to attach the framework and/or auxiliary connectors to the rooftop; non-penetrating mounting in which auxiliary components interconnect PV modules to one another; etc.). Thus, some traditional PV modules employ an extruded aluminum frame that supports the entire perimeter of the corresponding PV laminate. A lip of the aluminum frame extends over and captures an upper surface of the PV laminate.

Airborne dust, dirt, and other debris are constantly being deposited onto the PV laminate, which reduces the output from the PV module. Rain and other moisture captures dust and debris, thereby leaving concentrated areas of dust and debris as the water evaporates, forming localized areas of “soiling” on the PV module. The frame lip impedes, to some extent, drainage of moisture from the PV laminate surface. As such, moisture will collect along the PV laminate, especially at the lowest point of the PV laminate. For example, where a flat PV panel is installed in a horizontal orientation, for example on a roof, the weight of the panel itself and/or additional water can cause the panel to bend into a concave shape, thereby causing water to accumulate in and around the center of the panel. Such accumulated water, as noted above, causes debris and dust to accumulate within the wetted area and thus cause a localized area of soiling, for example, after the water evaporates.

Similarly, with a tilted PV module, moisture (and entrained debris) will travel (via gravity) toward the lowermost edge of the PV laminate, effectively pooling against the frame lip. As the moisture subsequently evaporates, it leaves behind dirt and debris. This soiling has the effect of shading nearby PV cells, and can thus significantly decrease performance of the PV module. More specifically, localized areas of soiling on a PV panel can cause the photovoltaic cell shaded by such soiling to become an electrical load in the circuit connecting the various cells of the PV laminate together. Thus, while the unshaded cells in the PV panel are producing electricity, the shaded cells can dissipate some of that generated energy in the form of waste heat, thus reducing PV panel efficiency. Additionally, such shading can cause current mismatches damage the cells and possibly lead to premature failures.

To perhaps address the above concerns, it has been suggested to machine cut several channels into the aluminum frame at one or more corners thereof, with the channels providing a region for liquid to drain off of the PV module. Once such device is believed to be available from Kyocera Corp., Solar Energy Division, of Kyoto, Japan.

### SUMMARY OF THE INVENTION

An aspect of at least one of the embodiments disclosed herein includes the realization that the upper surface of a PV module, such as the uppermost weather proof barrier, can be configured into a convex, upwardly bulging shape, without substantially affecting the overall solar collecting efficiency of a PV panel. As such, an upwardly bulged, convex shape of the outermost barrier of a PV panel can cause water droplets to flow away from the center of such a panel toward the edges thereby reducing localized areas of soiling which can negatively impact the electrical output of a PV panel.

Another aspect of at least one of the embodiments disclosed herein includes the realization that photovoltaic cells can be bent with a curvature sufficient to provide the above noted water flow effects without affecting the integrity of the photovoltaic cells. Thus, for example, where the photovoltaic cells are bent to match the curvature of a convex uppermost layer of the PV laminate, the cells and the uppermost layer can be bonded together, using the same techniques normally used for flat PV laminates, thereby eliminating optical aberrations that may result from using an upwardly convex outer layer over a flat layer of photovoltaic cells.

Thus, in accordance with at least one embodiment, a photovoltaic solar collector can comprise a photo electronic device configured to convert solar radiation into electrical power, the photo electronic device having a photo-sensitive surface arranged to be exposable to sunlight. An outer barrier member can be mounted relative to the photosensitive surface such that sunlight must pass through the outer barrier member to reach the photosensitive surface. The outer barrier member can comprise an outer surface arranged to be exposed to the environment and facing away from the photosensitive surface. The outer surface of the outer barrier member is convex.

In accordance with another embodiment, a method of making a photovoltaic solar collector can comprise bending an a photo electronic device configured to convert solar radiation into electrical power such that a photo sensitive surface of the photo electronic device is convex. The method can also comprise attaching a first member to the photo electronic device so as to hold the photo sensitive surface in the convex shape.

In accordance with yet another embodiment, a method of making a photovoltaic solar assembly can comprise mounting a photovoltaic solar collector such that a convex outer surface of the photovoltaic solar collector faces upwardly.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a perspective view of a prior art photovoltaic panel including a photovoltaic laminate supported by a framed structure;

FIG. 2 is an exploded view of the PV module illustrated in FIG. 1;

FIG. 3 is an enlarged top plan view of a PV laminate of the PV module of FIG. 1;

FIG. 4 is a schematic cross-sectional view of the PV module of FIG. 1;

FIG. 5 is an enlarged portion of a cross-section of the PV module of FIG. 1, illustrating accumulated water and debris adjacent a lip of the frame of the PV module illustrated in FIG. 1;

FIG. 6 is a schematic cross-sectional illustration of the PV module of FIG. 1, illustrating accumulated water and debris collected in a central area of the PV laminate;

FIG. 7 is a schematic perspective view of the PV laminate of FIG. 1 illustrating the accumulation of soiling at a center of the PV laminate;

FIG. 8 is a schematic perspective view of the PV laminate in FIG. 1 mounted at an inclination relative to horizontal and illustrating the accumulation of soiling at the lower edge thereof;

FIG. 9 is a schematic perspective view of a PV module construction in accordance with an embodiment;

FIG. 10 is a schematic sectional view of the PV module of FIG. 9, taken along line 2.-2.;

FIG. 11 is a cross-sectional view of the PV module of FIG. 9 and illustrating the effect of a load on the upper surface of the PV laminate;

FIG. 12 is a schematic perspective view of a further embodiment of a PV laminate with a schematic representation of soiling along the lateral edges of the laminate;

FIG. 13 is a schematic perspective view of a further embodiment of a PV laminate with a schematic representation of soiling along the longitudinal edges of the laminate;

FIG. 14 is a perspective view of another embodiment of a PV laminate, mounted at an angle relative to horizontal and including a schematic representation of soiling along the lateral edges thereof;

FIG. 15 is a perspective view of another embodiment of a PV module;

FIG. 16 is an enlarged cross-sectional view of a portion of the PV module of FIG. 15, illustrating accumulated water and debris at the lateral edge of the PV laminate;

FIG. 17 is a schematic diagram illustrating a method of manufacturing the PV laminate of FIGS. 9-16;

FIG. 18 is a schematic diagram of yet another method of manufacturing the PV laminate of the PV module of FIG. 11.

### DETAILED DESCRIPTION OF THE PREFERRED EMBODIMENT

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature.

“Locating connector”—The following description refers to devices or features being connected with a “locating connector”. As used herein, unless expressly stated otherwise, “locating connector” means that one element/node/feature is directly or indirectly joined to (or directly or indirectly communicates with) another element/node/feature with a mechanism that connects and also provides a locating function, such as for example but without limitation, alignment of elements/nodes/features or enhancing contact between two elements/nodes/features.

“Adjust”—Some elements, components, and/or features are described as being adjustable or adjusted. As used herein, unless expressly stated otherwise, “adjust” means to position, modify, alter, or dispose an element or component or portion thereof as suitable to the circumstance and embodiment. In certain cases, the element or component, or portion thereof, can remain in an unchanged position, state, and/or condition as a result of adjustment, if appropriate or desirable for the embodiment under the circumstances. In some cases, the element or component can be altered, changed, or modified to a new position, state, and/or condition as a result of adjustment, if appropriate or desired.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

“Maximum Effective Slope”—As used herein, maximum effective slope is used to describe the average slope of an upper surface of a PV laminate from the highest point to the closest edge. More particularly, the maximum effective slope would be determined by dividing the difference in height between the highest point on the upper surface of a PV laminate and the closest edge by the lateral distance between the highest point and the closest edge. In some embodiments, the upper surface of the PV laminate may be continuously curved and thus only one point on the surface might have the same value as the maximum effective slope.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second”, and other such numerical terms referring to structures do not imply a sequence or order unless clearly indicated by the context.

The inventions disclosed herein are described in the context of a photovoltaic module. However, these inventions can be used in other contexts as well.

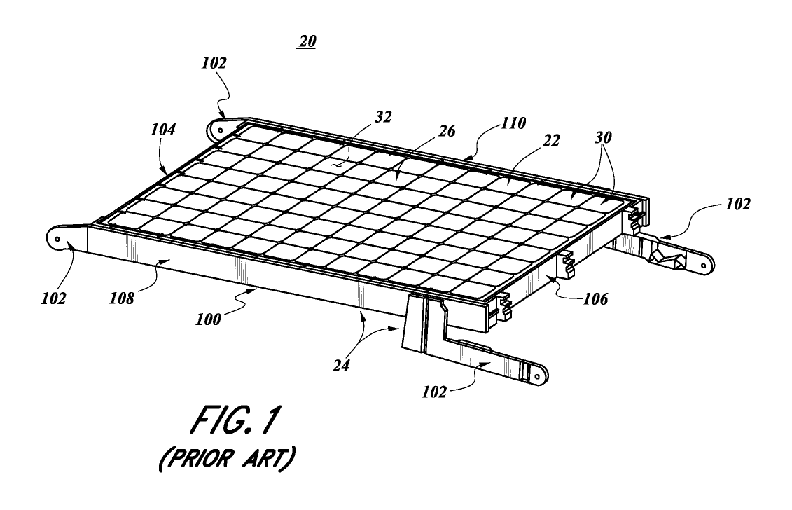

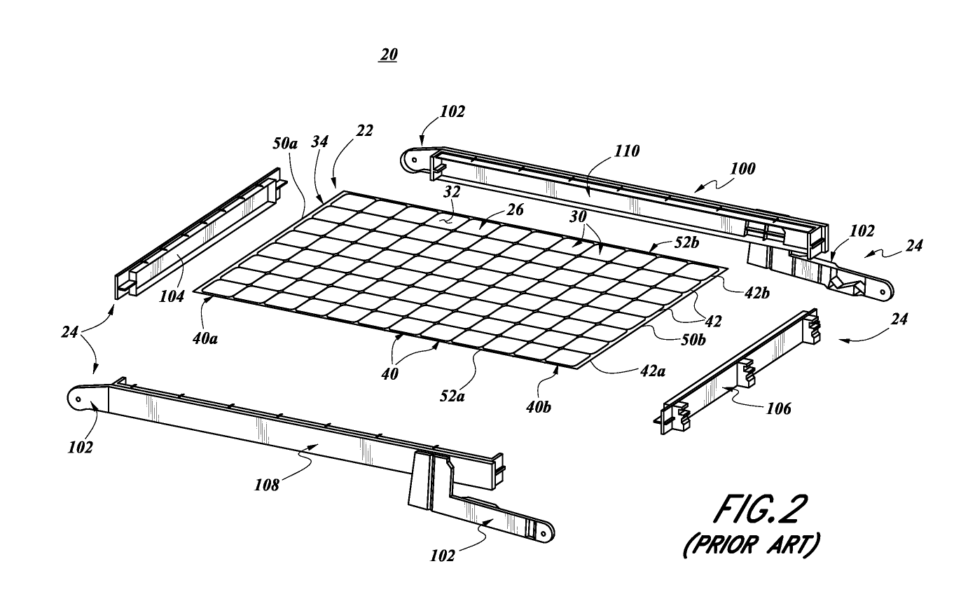

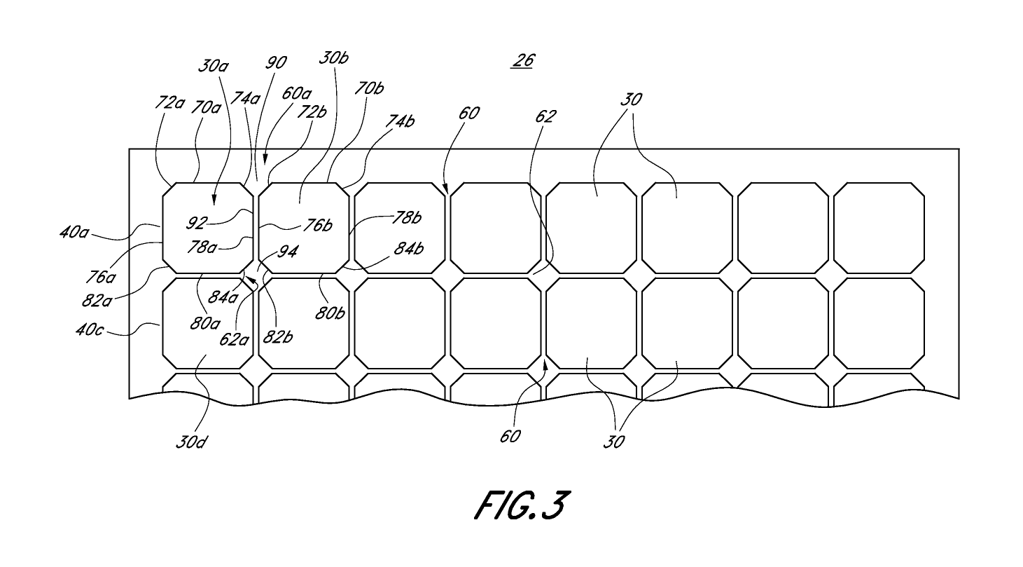

A known photovoltaic (PV) known module 20 is shown in FIGS. 1 and 2, similar to the PV module disclosed in U.S. Patent Publication No. 2009/0320908. Although the PV module 20 is a known prior art design, some of the features of the module 20 can be used with the embodiments illustrated in FIGS. 9-18. Thus, the components of the PV modules illustrated and described below with reference to FIGS. 9-18 that can be similar or the same as those components of the PV module 20 are identified with the same reference numerals, except that 1000 or 2000 has been added thereto. Thus, those components can be assumed to be constructed in the same, similar, or identical manner as those described below with reference to the PV module 20 illustrated in FIGS. 1-8, unless otherwise stated.

The PV module 20 includes a PV device 22 (referenced generally) and a frame 24. Details on the various components are provided below. In general terms, however, the PV device 22 includes a PV laminate 26 that is encased by the frame 24.

The PV device 22 can assume a variety of forms that may or may not be implicated by FIGS. 1 and 2. For example, the PV device 22, including the PV laminate 26, can have any form currently known or in the future developed that is otherwise appropriate for use as a solar PV device. In general terms, the PV laminate 26 consists of an array of PV cells 30.

The PV laminate 26 includes a weather-proof barrier 32 that forms the uppermost surface of the PV laminate 26. The illustrated PV laminate 26 includes a glass member that provides a weather-proof barrier for the PV cells 30. The glass layer is bonded to the PV cells 30 in a well-known manner. The PV cells 30 comprise backside-contact cells, such as those of the type available from SunPower Corp., of San Jose, Calif. Backside-contact cells include wiring leading to external electrical circuits are coupled on the backside of the cell (i.e., the side facing away from the sun upon installation) for increased area for solar collection. Backside-contact cells are also disclosed in U.S. Pat. Nos. 5,053,083 and 4,927,770, which are both incorporated herein by reference in their entirety. Other types of PV cells may also be used without detracting from the merits of the present disclosure. For example, the photovoltaic cells 30 can incorporate thin film technology, such as silicon thin films, non-silicon devices (e.g., III-V cells including GaAs), etc. Thus, while not shown in the figures, in some embodiments the PV device 22 can include one or more components in addition to the PV laminate 26, such as wiring or other electrical components.

Regardless of an exact construction, the PV laminate 26 can be described as defining a outermost upwardly facing weather proof barrier 32 and a perimeter 34 (referenced generally in FIG. 2). Additional components (where provided) of the PV device 22 are conventionally located at or along a back face of the PV laminate 26, with the back face being hidden in the views of FIGS. 1A and 1B.

The PV cells 30 are oriented so as to face toward the barrier 32 for receiving sunlight. With specific reference to FIGS. 2 and 3, the arrayed format of the PV cells 30 defines a plurality of rows 40 (40a, 40b) and a plurality of columns 42 (42a, 42b). The array of PV cells 30 can be described as including a first row 40a immediately proximate or adjacent a first perimeter end edge 50a of the PV laminate 26, and a second row 40b immediately proximate or adjacent an opposing, second perimeter end edge 50b. Similarly, a first column 42a is defined immediately proximate or adjacent a first perimeter side edge 52a, and a second column 42b is formed immediately adjacent an opposing, second perimeter side edge 52b. Although FIGS. 1-3 illustrate the PV laminate 26, and thus the arrayed PV cells 30, as having a rectangular form, other configurations are equally acceptable (e.g., the PV laminate 26 can have a square shape; the end edges 50a, 50b can be longer than the side edges 52a, 52b; etc.). Similarly, the number of PV cells 30 associated with the rows 40 and/or the columns 42 can be greater or lesser than the numbers reflected in FIGS. 1-3.

The PV cells 30 are identical in size and shape, and are uniformly distributed along the PV laminate. As a result, identical uniform spacings are defined between the PV cells 30.

FIG. 3 illustrates a portion of the PV laminate 26 in greater detail, including the first row 40a of the PV cells 30, as well as an immediately adjacent row 40c. Adjacent ones of the PV cells 30 of the first row 40a are separated by a column spacing 60. For example, the first row 40a includes first and second PV cells 30a, 30b separated by a column spacing 60a. An identically sized and shaped column spacing 60b is defined between the second PV cell 30b and a third PV cell 30c immediately adjacent the second PV cell 30b in the first row 40a. Similar column spacings 60 are established between adjacent PV cells of the remaining rows 40, for example as illustrated in FIG. 3 for the PV cells 30 of the immediately adjacent row 40c. Further, a row spacing 62 is established between adjacent ones of the PV cells 30 from adjacent rows 40. FIG. 3 also illustrates a first row spacing 62a between the first PV cell 30a of the first row 40a, and fourth PV cell 30d of the immediately adjacent row 40c that is otherwise immediately adjacent the first PV cell 30a. Once again, the row spacings 62 can all be identical in size and shape, and can further be identical to the column spacings 60.

With the above conventions in mind, the column spacings 60 and the row spacing 62 are uniform and identical in shape in some embodiments, with the particular shape being generated as a function of a shape of the PV individual cells 30. For example, FIG. 3 identifies the first PV cell 30a as having a shaped perimeter including a leading end segment 70a, opposing leading side segments 72a, 74a, opposing side segments 76a, 78a, a trailing end segment 80a, and opposing trailing side segments 82a, 84a. The second PV cell 30b has an identically shaped perimeter, with corresponding perimeter segments identified in FIG. 3 with similar numbers and the suffix “b”. Thus, the first column spacing 60a is defined between the leading side segment 74a of the first PV cell 30a and the leading side segment 72b of the second PV cell 30b; between the side segments 78a and 76b; and between the trailing side segment 84a and the trailing side segment 82b. In light of the octagonal-like shape of the PV cells 30, then, the first column spacing 60a includes or is defined by a leading portion 90, an intermediate portion 92, and a trailing portion 94. With the but one acceptable configuration of FIG. 2, the leading portion 90 tapers in width from the leading end segments 70a, 70b to the intermediate portion 92; conversely, the trailing portion 94 increases in width from the intermediate portion 92 to the trailing end segments 80a, 80b. As described below, features of the frame 24 (FIG. 1A) can be shaped in accordance with a shape of the column spacings 60. Although the PV cells 30 are illustrated as being generally octagonal in shape, a wide variety of other shapes are also applicable in accordance with principles of the present disclosure (e.g., square, rectangular, circular, non-symmetrical, etc.), with the resultant column spacings 60 and row spacings 62 having shape(s) differing from those shown.

With continued reference to FIGS. 1, 2, and 4, and with the above understanding of the PV laminate 26 in mind, the frame 24 generally includes framework 100 adapted to capture the perimeter 34 of the PV laminate 26. In some constructions, the frame 24 further includes one or more arms 102 extending from the framework 100 and configured to facilitate arrangement of the PV laminate 26 at a desired orientation relative to an installation surface as described below. As a point of reference, while FIG. 2 illustrates the framework 100 as including four frame members 104-110, a variety of other configurations are also acceptable.

FIG. 5 includes an enlarged cross-sectional view illustrating the connection between the PV laminate 26 and the first frame member 104. As shown, the first perimeter end edge 50a is located in the capture zone between the support surface 140 of the ledge 122 and the retention surface 160 of the lip 126, with the stop surface 150 of the shoulder 124 ensuring a desired spatial position of the first perimeter end edge 50a. An adhesive (A) can be employed to effectuate a more complete attachment between the PV laminate 26 and the first frame member 104.

With continued reference to FIG. 5, because the laminate 26 is generally flat, when W accumulates near the edge of the frame 104, for example, when the laminate 26 is mounted at a slight inclination relative to horizontal, the accumulated water W tends to trap and collect debris and D. As the W evaporates, the debris D is left behind creating a soiled area on the barrier 32. This debris casts a shadow S onto the cells 30, thereby affecting the output of the cells 30.

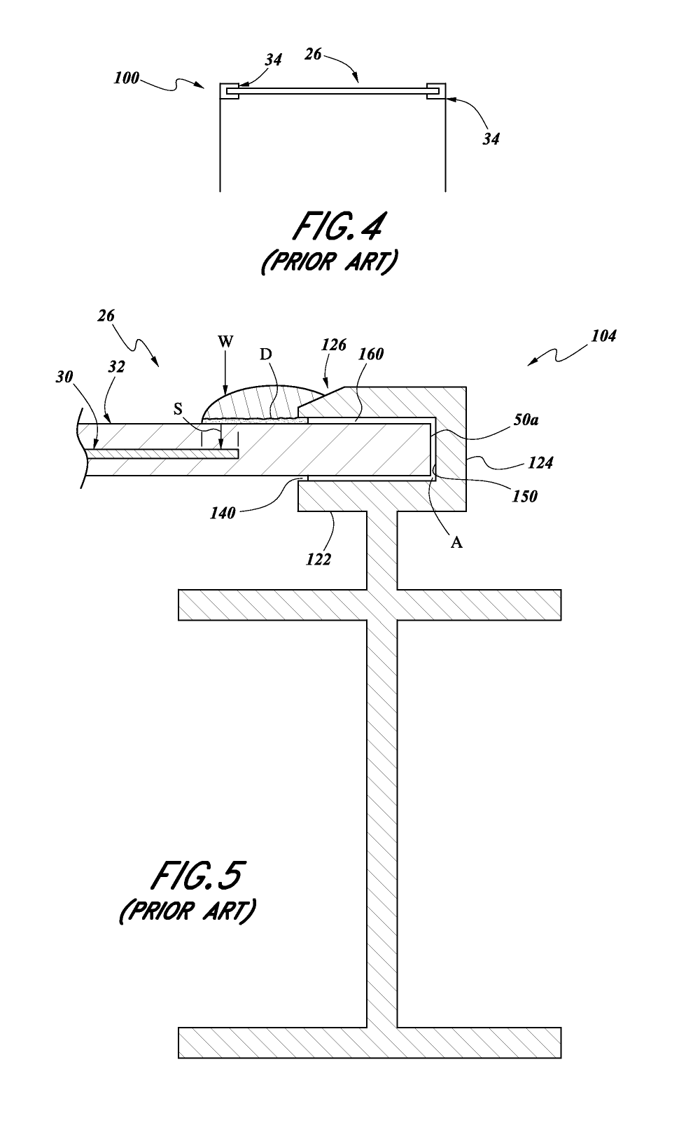

With reference to FIG. 6, depending on the thickness of the laminate 26, the laminate 26 can sag or bend downwardly, under its own weight, or under the additional weight of water W for example. This sagging of the laminate 26 creates a shallow bowl-shaped concavity in the laminate 26. As such, additional water from other parts of the laminate 26 tend to flow toward this bowl-shaped concavity. As shown in FIG. 7, as the W evaporates, the debris is left behind and creates an area of concentrated soiling, which can be in about of the laminate 26.

Additionally, in order to reduce overall weight and raw material costs, the materials used to form the upper surface of the laminate 26 is thin and light. Thus, when such PV laminates 26 are subject to wind, the laminate can vibrate and flex up and down, thereby fluctuating between convex and concave shapes. This fluctuation is known as “oil-canning”. Such a fluctuation can accelerate fatigue failures of the PV laminate 26.

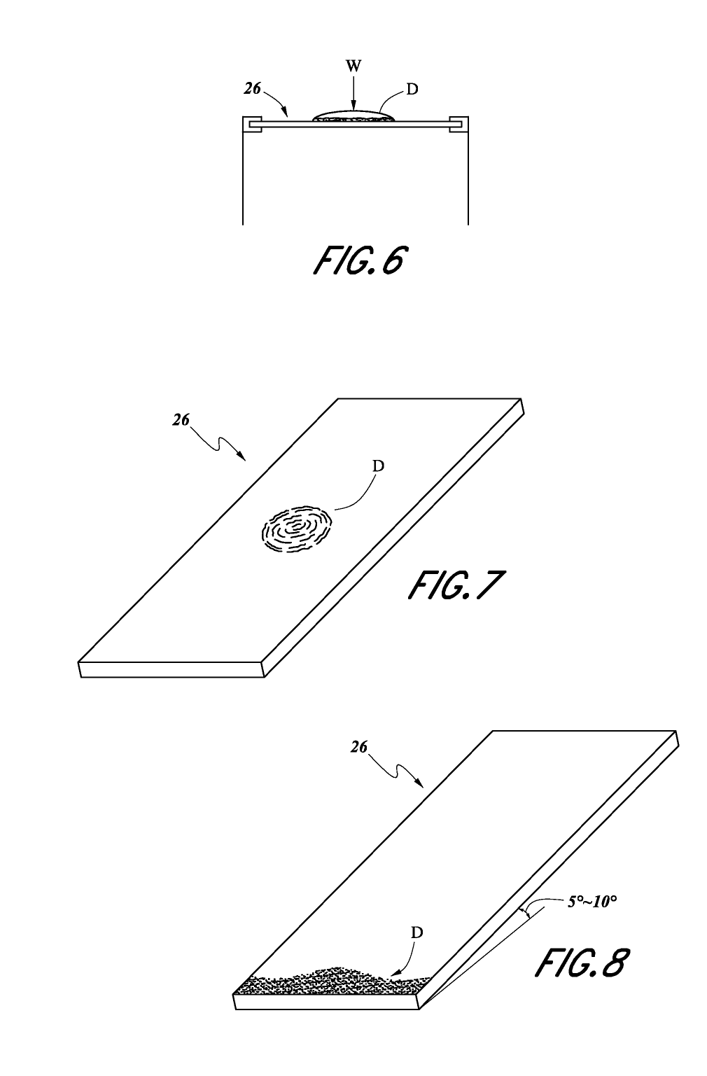

Similarly, even where the module 20 is mounted such that the laminate 26 is included relative to horizontal (5° to 10° from horizontal in the configuration of FIG. 8), water and debris can collect at the lowermost edge of the laminate 26. Thus, as noted above, as the W evaporates, debris and dust forming a concentrated area of soiling, can extend along the lowermost edge of the laminate 26. As noted above, these areas of concentrated soiling can cause the cells beneath the soiling to become an electrical load on the circuit including the cells, thereby consuming some of the energy generated by output by the other cells 30 that are not shaded by soiling.

FIG. 9 illustrates a PV module 1020 in accordance with an embodiment of a PV module having improved anti-soiling characteristics. Components of the PV module 1020 that correspond to similar structures in the PV module 20 have been identified with the same reference numeral, except that 1000 has been added to the reference numeral.

As shown in FIG. 9, the PV module 1020 can include a PV laminate 1026, a frame 1024 and a support device 1102 The frame 1024 supports the PV laminate 1026 around its peripheral edges. The support device 1102 supports the frame 1024 relative to the ground G. The support device 1102 can take any form. For example, the support device 1102 can be in the form of the legs 102 shown in FIG. 1, a combined support and wind deflector device, or a sun tracking system for adjusting the angle of the frame 1024 so as to track the movement of the sun.

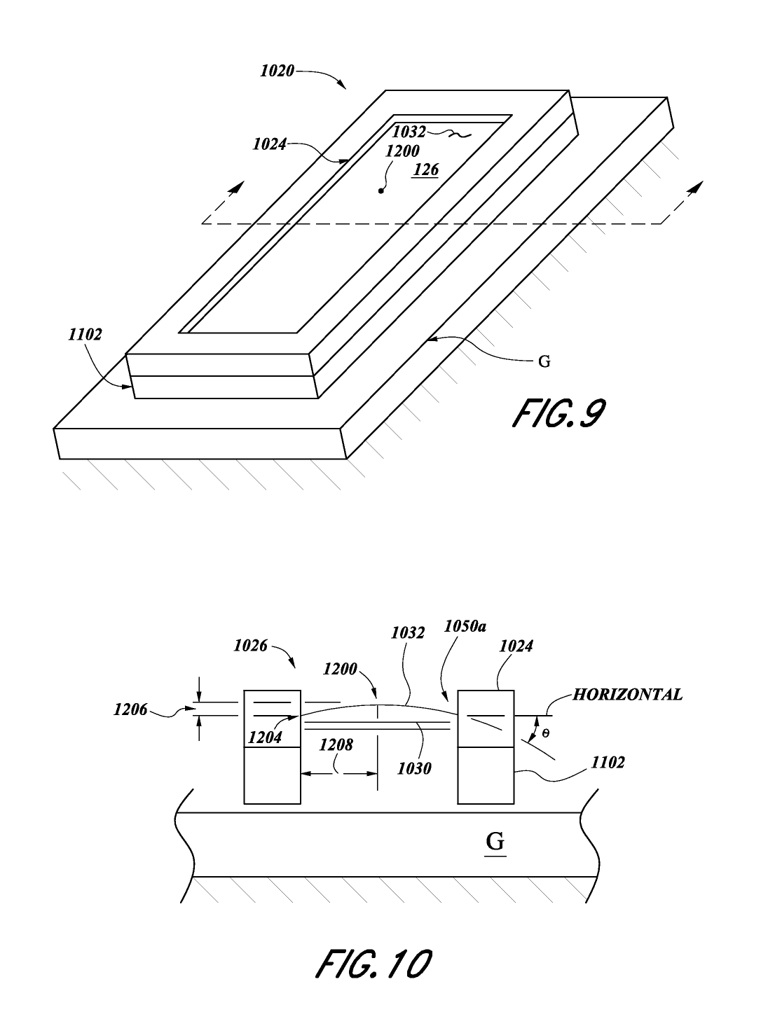

With reference to FIG. 10, the uppermost surface 1032 of the PV laminate 1026 can be arched upwardly, with a curvature about its longitudinal axis, a transverse axis, or a generally convex upwardly bulging shape. As such, as noted above, water and debris that might contact the barrier 1032 will tend to flow toward the edges of the PV laminate 1026, thereby reducing the amount of localized soiling that may create shadows on the cells 1030. The configuration of the barrier 1032 can be achieved in any known way. For example, the barrier 1032 could be made from a sheet of glass mounted in an arched or convex shape above the cells 1030. In some embodiments, the barrier 1032 can be formed from a material having a flat inner surface bonded with the cells 1030 and a varying thickness resulting in a convex outer surface 1032. In other embodiments, the entire laminate 1026 can be constructed in a configuration such that the barrier 1032 and the cells 1030 are in a convex configuration.

The magnitude of the convexity of the upper surface of the barrier member 1032 can be measured in any known manner. For example, the curvature of the upper surface of the barrier member 1032 can be measured in terms of its maximum effective slope. The maximum effective slope can be determined by, first, determining the relative height 1206 of the highest point 1200 on the PV laminate and the height of the closest point 1204 on a lateral edge of the upper surface of the barrier 1032. This relative height represents the “rise” of the maximum effective slope.

Next, the lateral distance 1208 from the highest point 1200 to the position of the closest point 1204 can be determined. This distance represents the “run” of the maximum effective slope. Thus, the maximum effective slope can be determined by calculating the sine of the ratio of the “rise” 1206 over the “run” 1208. In some embodiments, the maximum effective slope can be at least about 2°. In some embodiments, the maximum effective slope can be 15° or less. In other embodiments, the maximum effective slope can be between about 5° and about 10°. In other embodiments, the maximum effective slope can be at least about 2.8°.

The magnitude of the convexity of the upper surface of the barrier member 1032 can also be expressed as the slope of the peripheral edge of the PV laminate 1026. For example, the actual slope of the upper surface of the barrier member 1032 can be directly measured against horizontal. As shown in FIG. 10, the upper surface of the barrier member 1032, at the lateral edge 1050a extends at an angle □ relative to horizontal. In some embodiments, the angle □ can be at least about 1°. Additionally, the angle □ can be about 8° or less. In other embodiments, the angle theta Θ can be between about 2.5° and about 5°. In other embodiments, the angle theta Θ can be about 2.8°.

Additionally, in some embodiments, the upper surface of the barrier member 1032, in the area inward from the lateral edge 1050a, can be sloped at any of the angles □ noted above, with the terminal portion of the lateral edge 1050a being sloped at a lesser angle, such as 4° to 0°. As used herein, the term “terminal portion of the lateral edge 1050a” is intended to include the portion of the lateral edge connected to the frame 1024.

Other angles □ and maximum effective slopes can also be used. Additionally, the flow of water over the upper surface of the barrier member 1032 is different depending on the material used to form, the surface energy and electrical charge of the barrier member 1032. Thus, in some embodiments, the angle □ can be chosen to achieve the desired drainage and/or water flow characteristics.

Constructing the module 1020 with an upwardly convexly-shaped upper surface can provide additional advantages. For example, by providing the barrier member 1032 with a convex surface, the PV laminate 1026 can be stiffer, and thus better resist fluctuations such as “oil-canning” and the resulting fatigue failures.

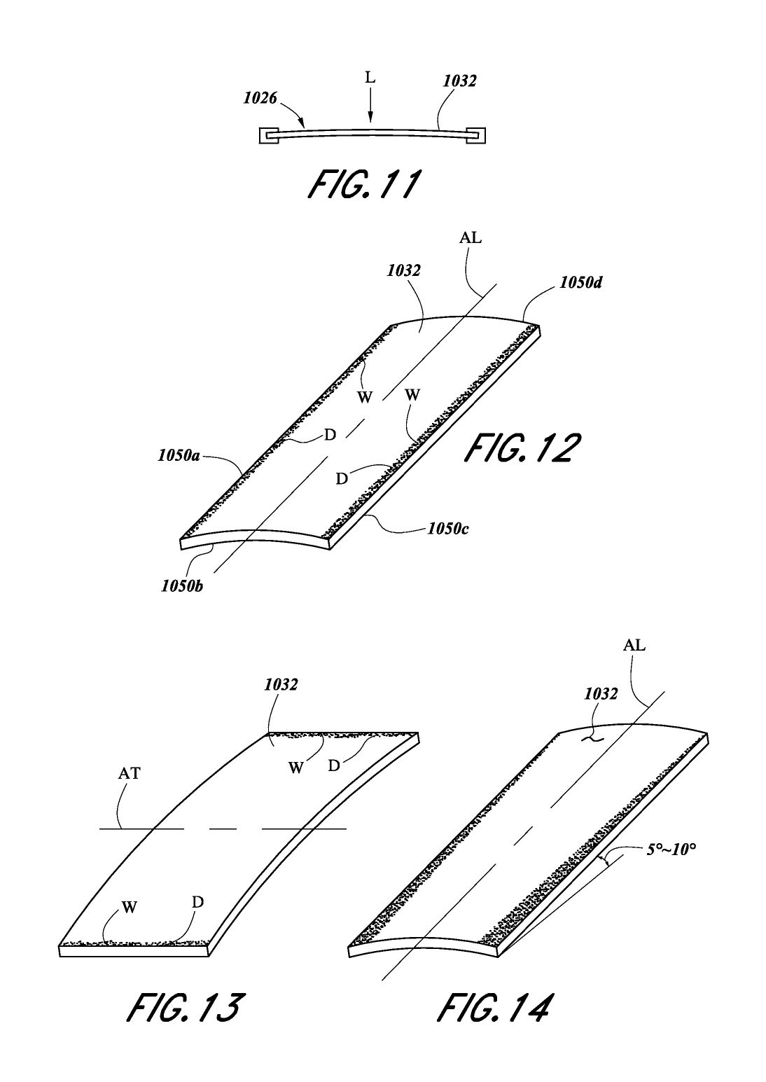

As shown in FIG. 11, the frame 1024 and/or the laminate 1026 are constructed with sufficient strength that the barrier 1032 retains the desired convex shape despite downward loads L applied to the barrier 1032. Thus, with the upwardly bulging convex shape of the outer barrier member 1032, when loads L are applied to the upper barrier member 1032, the upper barrier member 1032 retains the upwardly bulging convex shape. In other words, the outer barrier member 1032 is held with sufficient strength, either by way of its construction or the frame 1024, so as to retain the upwardly bulging convex shape when loads, such as those loads that may be caused by water, debris, wind, etc. are applied to the outer barrier member 1032. Thus, the outer barrier member 1032 retains its upwardly bulging convex shape so as to help water flow away from the center toward the edges thereof, despite such loads.

As noted above, the outer barrier member 1032 can be convexly curved in a single direction, as illustrated in FIGS. 12 and 14, in which the outer barrier member 132 is curved about its longitudinal axis AL. In other embodiments, the outer barrier member 1032 can be curved about its transverse axis AT. In the embodiments of FIGS. 12-14, the laminate 1026 is constructed in a manner such that the barrier member 1032 retains the convex shape when the laminate 1026 in a relaxed, unloaded shape, supported only by its peripheral edges 1050a-1050d.

With continued reference to FIG. 12, when a PV module incorporating the PV laminate 1026 is mounted generally horizontally, the upwardly bulging convex shape of the outer barrier member 1032 causes water W and debris D to flow towards the outer lateral edges 1050a, 1050c, of the outer barrier member 1032. Similarly, as shown in FIG. 14, if the corresponding PV module is mounted such that the outer barrier member 1032 is inclined relative to horizontal by a typical amount, such as for example, but without limitation, 5° to 10°, water W and debris D still flow outwardly toward the lateral edges 1050a, 1050c of the PV laminate 1026, but will tend to be more concentrated toward the lower longitudinal edge 1050b of the PV laminate 1026.

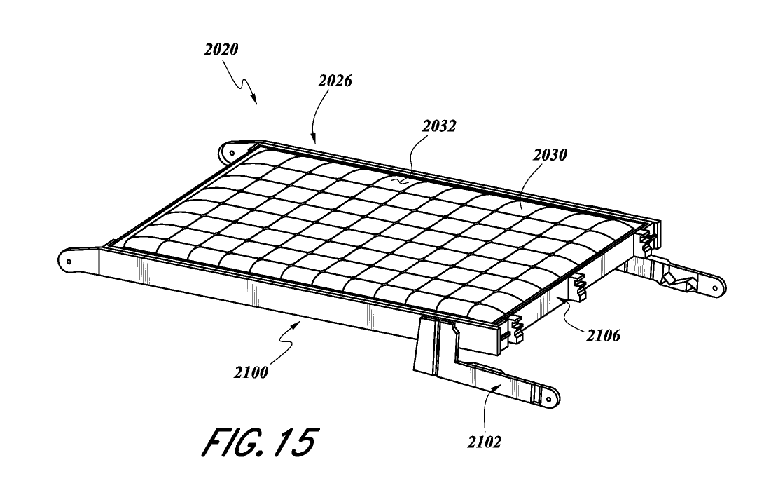

With reference to FIG. 13, as noted above, the barrier member 1032 can be curved about its transverse axis AT. As such, water W and debris D will tend to flow towards the longitudinal edges 1050a, 1050c of the barrier member 1032. Additionally, if such a barrier member 1032 is inclined relative to horizontal, then water W and debris D would tend to flow toward the lowermost edge 1050b, depending on the magnitude of the convex curvature of the barrier member 1032 and the angle of inclination relative to horizontal.

With reference to FIG. 15, a further embodiment of a PV module 2020 can include a roughly spherical, convexly shaped PV laminate 2026. In the illustrated embodiment, the PV laminate 2026 includes an outer barrier member 2032 and PV cells 2030 that are both provided with a convex upwardly bulging shape.

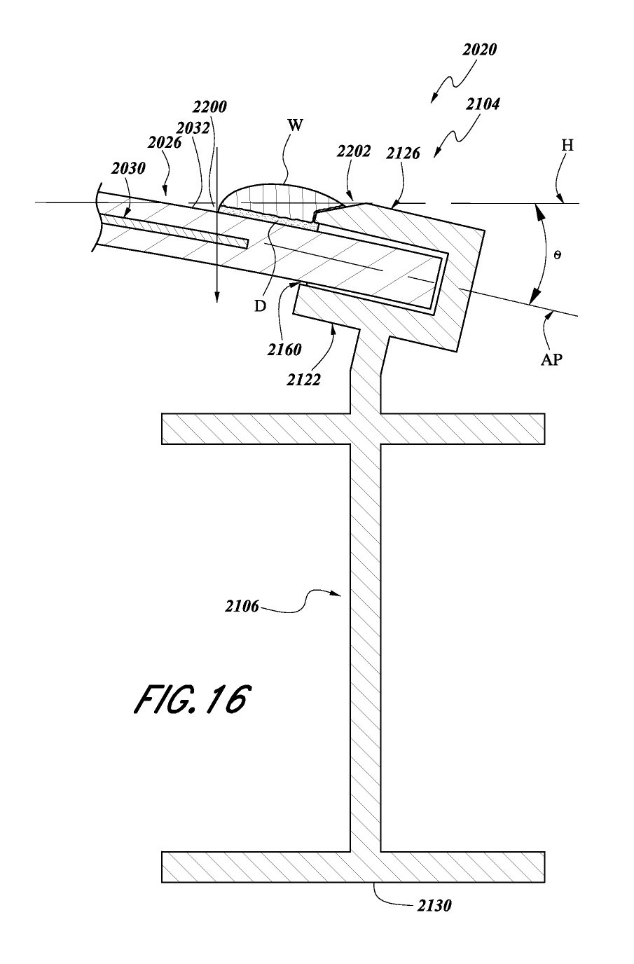

As shown in FIG. 16, the frame members 2106 can include an upwardly angled head such that the lip 2126 and the ledge 2122 are inclined upwardly such that the space 2160 opens and faces at an upward angle. More specifically, as shown in FIG. 16, the edge 2050a of the PV laminate 2026 extends into the capture zone defined between the ledge 2122 and the lip 2126, and extends along a peripheral axis AP.

In the illustrated embodiment, the PV laminate 2026 is constructed or held in place such that the peripheral axis AP, is inclined relative to horizontal H by an angle theta Θ (when measured with the laminate 2026 laid in on a horizontal surface). In some embodiments, the angle theta Θ is at least about 1°. Other angles Θ can also be used, such as those noted above with reference to the non-limiting embodiments of FIGS. 9-14.

As shown in FIG. 16, a point 2200 on the upper surface of the barrier member 2032 that is above the edge of the PV cell 2030 is at about the same vertical height as the uppermost surface 2202 of the upper support ledge 2122. Thus, as water W and debris D collect near the upper ledge 2122, the accumulated water can drain over the top of the uppermost surface 2202 of the ledge 2122 and off of frame member 2106. Although the surface tension in the accumulated water W can vary depending on impurity content in the water, the state of the surfaces of the barrier member 2032 and the uppermost surface 2202 of the ledge 2122, the size and shape of the accumulated water W will vary. However, the potential for soiling at a point on the outer barrier member 2032 above a PV cell 2030 is greatly reduced.

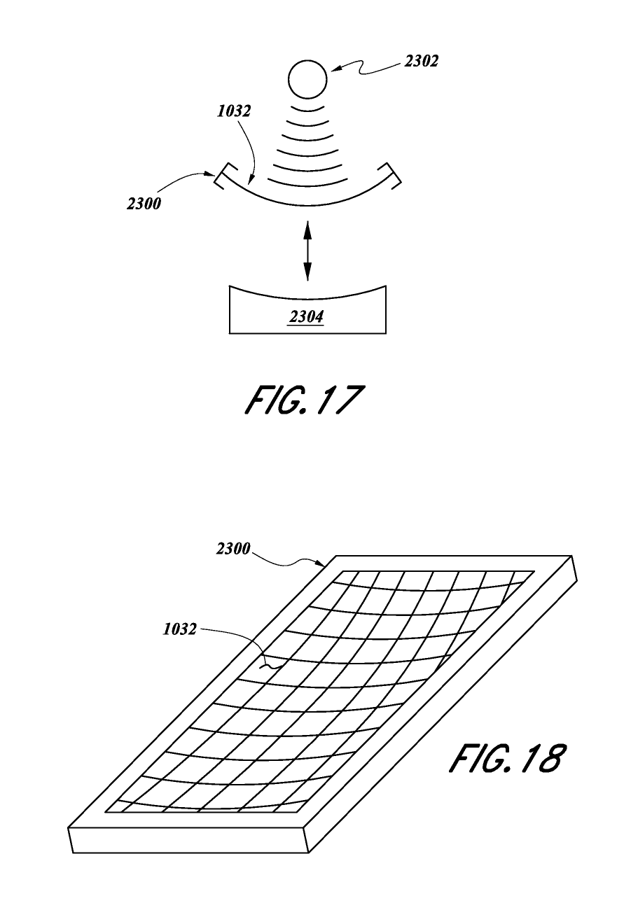

With reference to FIG. 17, a method of manufacturing PV module with an upwardly bulging convex outer barrier member can be performed in accordance with any known manner. For example, with reference to FIG. 17, the outer barrier member 1032 can be held in a support frame 2300 and heated with a heat source 2302 to cause the barrier member 1032 to sag into the desired shape. The heat source 2302 can be removed and the member 1032 can be allowed to cure in the convex shape. Optionally, a mold 2304 can be used to allow the barrier member 1032 to be hardened with the desired curvature.

In some embodiments, with the barrier member 1032 shaped as such, the PV cells 1030 can then be bonded to the barrier member 1032. As noted above, typically, the photovoltaic cells 1030 can be bent by a reasonable amount allowing the cells to bend and follow the curvature of the barrier member 1032. The PV cells 1030 can be bonded to such a curved barrier member 1032 in any known manner. In some embodiments, adhesive can be spread over the outer surfaces of a flat member with PV cells 1030, then two flat barrier members 1032 can be applied to the outer surfaces of the cells 1030. With the adhesive still uncured, the cells 1030 and barriers members 1032 can be bent together in the desired shaped and allowed to cure in the desired bent shape. In some embodiments, the weight of the cells 1030 and barrier members 1032 is enough to cause sufficient bending. Optionally, additional weights can be placed on the cells 1030 and barrier members 1032 to cause additional bending to hold these members in the desired shape until sufficiently cured to retain the desired shape.

In some embodiments, with reference to FIG. 17, the support frame 2300 supports only two opposite edges of the barrier member 1032. As such, the resulting barrier member 1032 would be in the form illustrated in FIG. 12, 14, or 13.

With reference to FIG. 18, the frame member 2300 can support all four edges of the barrier member 1032. As such, the barrier member 1032 will be shaped into a roughly spherical shape.

Providing a PV module with an upper surface that has an upwardly convex shape can provide additional advantages. For example, when sunlight (at approximately “noon”) reaches the upper surface of a PV module having a convex upper surface, such as any of those described above with reference to FIGS. 9-18, the sunlight impacting the central area of the PV laminate is largely absorbed by the central area of the PV laminate. This is because that portion of the upper surface of the PV laminate is closest to perpendicular relative to the angle of incidence of the sunlight onto the upper surface of the laminate. The sunlight impacting the edges of such a convex upper surface, however, can be reflected laterally. This lateral reflection can be caused by the non perpendicular angle of incidence of the sunlight onto the upper surface of the laminate. Even flat PV laminates reflect some sunlight laterally.

However, in a system including an array of PV modules, wherein two adjacent PV modules have upwardly convex upper surfaces, sunlight reflected by parts of the upper surface can be absorbed by the adjacent PV module having a convex upper surface. For example, because the upper surface of the PV module is upwardly convex, some of that surface can be oriented at an elevation and angle sufficient such that the sunlight laterally reflected from one PV module impacts the upper surface of the adjacent PV module and is thus absorbed and converted into electrical energy. As such, the total amount of absorbed sunlight can be increased. This benefit can be further enhanced where the photosensitive device of the PV laminate (i.e., the photovoltaic cells) are also convexly shaped along with the corresponding convex upper surface of the PV module.

Photovoltaic modules with flat upper surfaces can create lateral reflections. However, because such PV modules are normally mounted in orientations in which the upper surfaces are roughly coplanar and/or parallel, lateral reflections of sunlight from one PV module would not normally project along a path that would impact the upper surface of another adjacent PV module so that it could be absorbed.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A photovoltaic solar collector comprising:
a photo electronic device configured to convert solar radiation into electrical power, the photo electronic device having a photo-sensitive surface arranged to be exposable to sunlight; and
an outer barrier member mounted relative to the photosensitive surface such that sunlight must pass through the outer barrier member to reach the photosensitive surface, the outer barrier member comprising an outer surface arranged to be exposed to the environment and facing away from the photosensitive surface;
wherein the outer surface of the outer barrier member is convex.

2. The photovoltaic solar collector according to claim 1, wherein the outer barrier member is shaped to retain the convex shape of the outer surface when it is in a resting state.

3. The photovoltaic solar collector according to claim 1, wherein the outer surface of the outer barrier member is sufficiently convex so as to cause water to flow away from a central area of the outer surface toward edges of the outer surface when the photovoltaic solar collector is at rest and facing upwardly.

4. The photovoltaic solar collector according to claim 1, wherein a first slope of the outer surface, from a center of the outer surface to a point on an edge of the outer surface that is closest to the center, is at least about 2 degrees.

5. The photovoltaic solar collector according to claim 4, wherein the first slope is no more than about 15 degrees.

6. The photovoltaic solar collector according to claim 1, wherein a first slope of the outer surface is about 1 degree.

7. The photovoltaic solar collector according to claim 6, wherein the first slope is no more than about 8 degrees.

8. The photovoltaic solar collector according to claim 6, wherein the first slope is between about 2.5 degrees and about 5 degrees.

9. The photovoltaic solar collector according to claim 1, wherein the photo sensitive surface of the photo electronic device extends along the convex shape of the outer surface of the outer barrier member.

10. The photovoltaic solar collector according to claim 1, wherein the photo electronic device comprises at least one silicon photovoltaic cell, and wherein the outer barrier member is bonded to the photo electronic device.

11. The photovoltaic solar collector according to claim 10, wherein the outer barrier member and the photo electronic device have a flat shape when in a relaxed state and separated from each other, and are bonded together while being bent into the convex shape, thereby remaining in a stressed state when at rest in the convex shape.

12. The photovoltaic solar collector according to claim 10, wherein the outer barrier member is in the convex shape when in a relaxed state and separated from the photo electronic device, and wherein the outer barrier member and the photo electronic device are bonded together while the photo electronic device is bent into the convex shape.

13. The photovoltaic solar collector according to claim 1, additionally comprising a frame supporting the photovoltaic solar collector, wherein the photovoltaic solar collector has a flat shape when at rest and separate from the frame, and wherein the frame engages the edges of the photovoltaic solar collector and holds the photovoltaic collector in a stressed state in the convex shape.

14. The photovoltaic solar collector according to claim 1, additionally comprising a frame supporting the photovoltaic solar collector, the frame comprising at least first and second edge support portions supporting opposite edges of the photovoltaic solar collector, the first and second support portions being positioned at about a same elevation, and holding the opposite edges of the photovoltaic solar collector such that the outer surface extends upwardly away from the opposite edges.

15. The photovoltaic solar collector according to claim 14, wherein the first and second edge support portions comprise first and second channels, respectively, each of the first and second channels having open ends which face toward each other and at an upwardly skewed angle.

16. The photovoltaic solar collector according to claim 1, wherein the outer surface of the outer barrier member is rectangular in plan view and the convex shape is approximately partially spherical.

17. A method of making a photovoltaic solar collector, comprising:
bending an a photo electronic device configured to convert solar radiation into electrical power such that a photo sensitive surface of the photo electronic device is convex; and
attaching a first member to the photo electronic device so as to hold the photo sensitive surface in the convex shape.

18. The method according to claim 17, wherein the step of attaching comprises bending a barrier member and fixing the bent barrier member to the photosensitive surface.

19. The method according to claim 18, wherein the step of fixing comprises bonding.

20. The method according to claim 17, wherein the step of attaching comprises attaching the photoelectric device to a frame, wherein the frame resists a resiliency of the photoelectric device that biases the photoelectric device toward a flat, non-convex shape.

21. The method according to claim 17, wherein the step of bending comprises bending the photo electronic device until it is sufficiently convex so as to cause water to flow away from a central area of the first member toward edges of the first member when the photovoltaic solar collector is at rest and facing upwardly.

22. The method according to claim 17, wherein the step of bending comprises bending the photo electronic device until a first slope of the outer surface of the first member, from a center of an outer surface of the first member to a point on an edge of the outer surface that is closest to the center, is at least about 2 degrees.

23. The method according to claim 22, wherein the first slope is no more than about 15 degrees.

24. The method according to claim 22, wherein the step of bending comprises bending the photo electronic device such that a first slope of an outer surface of the first member is at least about 1 degree.

25. A method of making a photovoltaic solar assembly comprising:
mounting a photovoltaic solar collector such that a convex outer surface of the photovoltaic solar collector faces upwardly.
